(19) United States
(12) Patent Application Publication
(10) Pub. No.: US 2012/0052611 A1
(43) Pub. Date: Mar. 1, 2012

(54) Method and device for treating a wafer

(75) Inventor: Werner Maurer, Freudenstadt (DE)

(73) Assignee: Gebr. Schmid GmbH, Freudenstadt (DE)

(21) Appl. No.: 13/294,569

(22) Filed: Nov. 11, 2011

Related U.S. Application Data
(63) Continuation of application No. PCT/EP2010/056555, filed on May 12, 2010.

(30) Foreign Application Priority Data
May 13, 2009 (DE) 10 2009 022 337.1

(51) Int. Cl. H01L 31/18; C25D 17/06; C25D 17/02

(52) U.S. Cl. 438/61; 204/202; 257/E31.124

(57) ABSTRACT

In a method for continuously coating a wafer for solar cell production, in a coating bath comprising metal such as nickel, copper or silver, said metal is deposited on the wafer. The wafer is introduced into the coating bath and, at a point in time at which the wafer already extends into the coating bath with a first region, but does not extend into it with a second region, a current surge is effected at the second region of the wafer, This initiates the electrodeposition of the metal on the first region of the wafer extending into the coating bath for a subsequent automatic coating with the wafer having been completely introduced into the coating bath, also on the remaining area of said wafer, without a further current surge or current flow.

### CROSS-REFERENCE TO RELATED APPLICATIONS

This application is a continuation of PCT Application No. PCT/EP2010/056555, filed May 12, 2010, and claims priority to DE 10 2009 022 337.1 filed May 13, 2009, the disclosures of which are hereby incorporated by reference in their entirety.

### FIELD OF APPLICATION AND PRIOR ART

The invention relates to a method for treating a wafer for solar cell production in a continuous method in a coating bath, and to a device or treatment apparatus suitable for carrying out this method.

It is known to apply chemically depositable metals to wafers for solar cell production by the application of a voltage to the wafers. In this case, there are a large number of electrical contact means for the solar cell wafers, for example in the form of stationary sliders, moving contact rollers or the like. However, such electrical contact-connection cannot always be carried out without the risk of mechanical damage to the solar cell wafer. Furthermore, considerable outlay is involved in providing contact means for the entire length of the continuous passage through a coating bath and also maintaining them, in particular cleaning them.

### OBJECT AND HOW IT IS ACHIEVED

The invention is based on the object of providing a method mentioned in the introduction and a device mentioned in the introduction with which disadvantages of the prior art can be avoided and, in particular, contact-connection problems can be reduced or avoided in conjunction with a practical construction of a device for carrying out the method.

This object is achieved by means of a method comprising the features of claim 1 and also a device comprising the features of claim 16 or 17. Advantageous and preferred configurations of the invention are the subject matter of the further claims and are explained in greater detail below. Some of the features enumerated below are mentioned only for the method or only for the device. However, irrespective of this they are intended to be applicable both to the method and to the device. The wording of the claims is incorporated by express reference in the content of the description.

It is provided that, in the coating bath, metals, in particular copper, silver or nickel, or metal layers generally or metal structures are deposited on the wafer. According to the invention, in the method, a wafer is introduced into the coating bath and, at a point in time at which said wafer already extends into the coating bath with a front first region, while said wafer does not yet extend into the coating bath with a rear second region, a short current surge is applied or a short current flow is effected at said second region of the wafer in order to initiate an automatic deposition of the metal on the first region of the wafer extending into the coating bath. In this case, the first region has to extend into the coating bath with top side and underside for the electrical contact-connection. Said generation of a current surge or current flow can be effected in various ways, which will be discussed in even greater detail below. The wafer is then moved further into the coating bath for a subsequent more extensive coating respectively of the part or of the increasingly larger first region that actually already extends into the coating bath. For this further coating of exactly this wafer, a further current surge or current flow or application of voltage is then no longer required. In particular, after the first short current surge, even in the situation if the rear second region of the wafer that is not yet situated in the coating bath should be larger, no further current surge or current flow is necessary. It has surprisingly emerged in the context of the invention that an abovementioned short current surge suffices to initiate the deposition of the corresponding metal from the coating bath onto the wafer. After this initiation, the coating process proceeds automatically and does not need to be initiated anew or maintained by current flow. The duration of such a short current surge is advantageously a few seconds, particularly advantageously less than two seconds, and can even be shorter than one second.

Depending on the manner in which the current surge is generated, what can advantageously be achieved thereby is, primarily, that the current surge can be effected in a region of the wafer, namely the second region, which is still outside the coating bath and therefore as it were always clean and free of chemical solvents, while the front first region is already in contact with the coating bath. Light sources or contact means or the like therefore do not need to be provided in the coating bath and therefore do not need to be provided in contact with the chemical, which considerably improves and simplifies their design, operation and maintenance. Owing to the electrical conduction properties of an abovementioned wafer, the generation of a current surge at a second region of the wafer suffices to initiate or instigate the coating at a different, first region. It is then effected automatically increasingly on the entire wafer when the latter is gradually introduced completely into the coating bath.

In accordance with a fundamental configuration of the invention, the application or generation of the short current surge can be effected by the second region of the wafer being irradiated with light. For this purpose, a correspondingly designed light source can be provided, for example one or two linear light sources transversely with respect to the continuous-passage direction of the wafer. Thus, the second region of the wafer that is not yet situated in the coating bath is irradiated with light over the largest possible area in order, at a high continuous-passage rate, to achieve sufficiently intensive irradiation for the generation of a sufficient current surge.

The irradiation of the wafer with light or a contact-connection can be effected from one side. It can be effected either from below by means of a light source fitted below the continuous-passage path or from above by means of a light source correspondingly fitted above said continuous-passage path. Crucial criteria here may be firstly the space conditions at a coating apparatus and also the question as to on which side of the wafer a metal deposition is intended to be effected. A metal deposition on the underside of the wafer is regarded as advantageous since, in a continuous method, it can more easily be kept in constant contact with the treatment liquid or the coating bath over the whole area. For the fundamental functioning and also for the implementation of such initiation of a metal deposition in a coating bath by means of irradiation, that is to say a light-induced metal deposition, reference is made to U.S. Pat. No. 5,882,435 and also EP 542 148 A1.

In accordance with another fundamental configuration of the invention, the short current surge is generated by voltage being applied to the second region of the wafer, that is to say that rather than a light-induced current surge an electrical contact-connection is effected. In this case, corresponding contact means, which can be designed in a manner as known from the prior art and described in the introduction, are advantageously arranged outside the coating bath. They advantageously extend to just before the coating bath, such that it is firstly ensured that they do not come into contact with the coating bath, in order to avoid the problems mentioned above. In the case of a current surge as a result of direct electrical contact-connection too, a very short current surge with the abovementioned time durations suffices, such that the contact means also do not have to extend over a particularly long length. It therefore suffices, in the case of wafers that are not particularly large, for example, if, with the first region having already been immersed in the coating bath, only a few centimetres of the second region still protrude in order that the contact means can bear here on the second region or an illumination is effected for the short current surge. Particularly suitable contact means are rotating contact rollers such as are known from US 2008/116059 A1, for example.

The contact means bear advantageously only on that side of the wafer which is to be coated, particularly advantageously, as described above, on the lower side. Therefore, it is only here, moreover, that contact means are to be provided. The applied voltage is a DC voltage having negative polarity at the lower side of the wafer.

In accordance with a further embodiment of the invention, a current surge can be effected or irradiation with light or application of voltage can be performed until the wafer has been moved completely into the coating bath. The time during which the protruding second region can be reached is then maximally utilized. As described above, the time can also be chosen to be shorter since it has emerged in the context of the invention that even very short current surges having a duration of, for example, less than 1 second suffice for initiating the coating.

In the coating bath, the wafer is guided in such a way that it is at least partly immersed or wetted with the coating bath by both sides, that is to say top side and underside. The coating can then begin. Advantageously, the wafer, of course, when it has been completely introduced into the coating apparatus, is also completely immersed in the coating bath.

One application of a metallic coating of a wafer by means of the method described here and in the device described here is the coating of a side of the wafer for solar cells with elongate conductor fingers, for which purpose nickel or copper is appropriate as the metal. The precise structure to be produced is produced by pretreatment of the wafer surface, as is generally known.

These and further features emerge not only from the claims but also from the description and the drawings, wherein the individual features can be realized in each case by themselves or as a plurality in the form of subcombination in an embodiment of the invention and in other fields and can constitute advantageous and inherently protectable embodiments for which protection is claimed here. The subdivision of the application into individual sections and sub-headings do not restrict the general validity of the statements made thereunder.

### BRIEF DESCRIPTION OF THE DRAWINGS

Exemplary embodiments of the invention are illustrated schematically in the drawings and are explained in greater detail below. In the drawings:

FIG. 1 shows a schematic lateral sectional illustration through a coating apparatus with electrolytic contact-connection for the initial current surge, and

FIG. 2 shows a similar sectional illustration of an alternative coating apparatus with luminous means for an initial current surge.

### DETAILED DESCRIPTION OF THE EXEMPLARY EMBODIMENTS

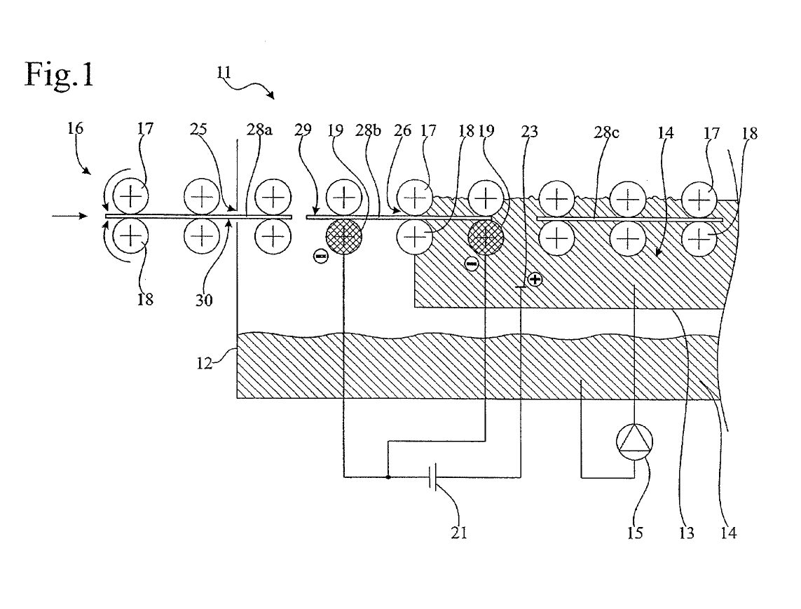

FIG. 1 illustrates a coating apparatus 11 such as can be embodied in accordance with a first variant of the invention. The coating apparatus 11 has an outer tank 12 with an outer lock 25. A coating tank 13 with the bath 14 is situated therein. The bath 14 has a corresponding coating liquid in which a metal is dissolved, for example those such as copper, silver or nickel as mentioned in the introduction. Furthermore, a pump 15 is provided in order to pump coating liquid that has run out or overflowed from the outer tank 12 into the coating tank 13 if appropriate together with a cleaning step, filtering step and/or additional enrichment.

A transport path 16 is provided through the coating apparatus 11, which runs on a single continuous plane in the present case. The transport path 16 has a multiplicity of upper transport rollers 17 and a multiplicity of lower transport rollers 18, which are driven at least in part in order to transport a substrate or a wafer 28, which will be described in even greater detail below. Furthermore, two cathodic rollers 19 are illustrated instead of lower transport rollers 18 that are otherwise arranged at this location. Said cathodic rollers 19 are provided near an inner lock 26 into the coating tank 13, which will be explained in even greater detail below. The cathodic rollers 19 are furthermore connected to a current source 21, or to the negative pole thereof. The current source 21 is furthermore connected by its positive pole to an anode 23 in the coating tank 13 or in the bath 14 in order to apply a voltage that can be generated by a DC rectifier in order that a current that brings about or initiates a coating then flows.

With regard to function it can be stated that the wafers 28 are introduced coming from the left on the transport path 16, to be precise with their top side 29—relative to this treatment step—upwards and the corresponding underside 30 downwards. The illustration shows three wafers in three positions, namely the wafer 28a, the wafer 28b and the wafer 28c, representative of the respective position.

The wafer 28a or generally a wafer at this position is already situated in the coating apparatus 11, but is still situated before the inner lock 26 to the coating bath 14 and before the cathodic rollers 19. Therefore, nothing is done yet to this wafer.

As soon as the wafer 28b on the transport path 16 comes into contact with the left-hand cathodic roller 19, it is indeed connected to the negative pole of the current source. However, no current can flow yet. If the wafer 28 enters through the inner lock 26 into the bath 14 and is wetted there with the bath 14 on its underside 30, but also on its top side 29, and is therefore connected to the positive pole of the current source 21 via the anode 23, a current flows and the electrolytic coating with the metal from the bath 14 on the underside 30 begins. If the right-hand cathodic roller 19 is not provided, then the wafer 28b is connected both to the left-hand cathodic roller 19 and to the anode 23 only for approximately as long as it has been introduced into the bath 14 approximately to an extent of at most half of said wafer. This suffices, however, to initiate the coating as described in the introduction. Once the coating process is under way, a temporary electrolytic coating is started which builds up a thin metal layer from the bath 14 on the underside 30. As a result of corresponding chemical deposition or coating from the bath 14, the coating with the metal then continues. The bath 14 is designed accordingly for this purpose. By virtue of the fact that the left-hand cathodic roller 19 is arranged outside the bath 14, there are no contamination problems here, or it is not coated with metal.

In order to have the effect that not only the front region of the wafer 28 is electrolytically coated, but also the rear region, and a proper entire coating is thus ensured, the right-hand cathodic roller 19 can actually be provided. The latter ensures that the wafer 28 already runs completely in the bath 14 as long as it is still connected to the current source 21 or as long as the electrolytically constrained coating proceeds. For this purpose, the right-hand cathodic roller 19 could also be arranged even further towards the left and near the inner lock 26. Under certain circumstances, it is even possible to form the lower transport roller 18 directly at the inner lock 26 as a cathodic roller 19. In this case, here as well there is then admittedly the problem that the inner cathodic roller 19 is metallically coated and then has to be correspondingly cleaned. However, this is tenable for a good coating. It is at least possible in this way for the number of cathodic rollers 19 running in the bath 14 to be substantially restricted to one.

Overall, with this arrangement in which even one cathodic roller 19 arranged within the bath 14 is arranged very near the beginning of the coating or near the inner lock 26, a coating is initiated electrolytically and then continued chemically.

In the position of the right-hand wafer 28c, the latter is no longer connected at all to the current source 21, but rather is now only guided by the transport rollers 17 and 18 on the transport path 16. Here only a chemical coating from the bath 14 on the underside 30 is then effected, but it actually continues without any problems by virtue of the initiation described above.

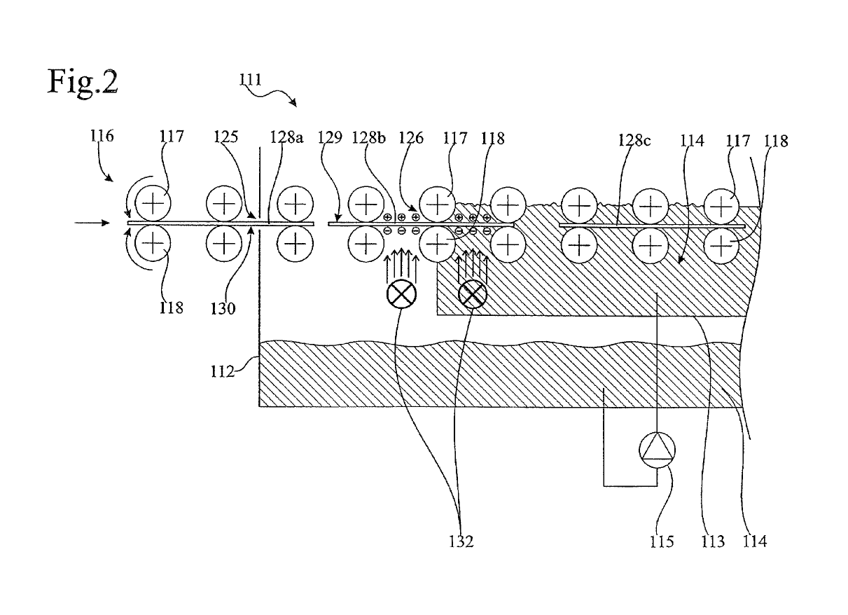

In a modified coating apparatus 111 in accordance with FIG. 2, provision is likewise made of an outer tank 112 with a coating tank 113 therein, which accommodates a bath 114. A pump 115 for circulation is also provided. On a transport path 116 having upper transport rollers 117 and lower transport rollers 118, all of which are designed completely identically, at least in each case within or outside the bath 114, wafers 128 are transported in accordance with FIG. 1 in the positions 128a, 128b and 128c from left to right.

Near the inner lock 126, light sources 132 are provided below the wafers 128, that is to say with the beam direction towards the undersides 130. Said light sources can be embodied for example in the form of luminescent tubes or LEDs arranged in series with the emission direction upwards.

The wafer 128a on the far left has already passed through the outer lock 125 of the outer tank 112, but is not yet irradiated with light and so nothing happens here yet.

The middle wafer 128b, on its path coming from the left with the right-hand front region, is irradiated on its underside 30 by the left-hand light source 132, and so the charge carriers already separate here. As soon as the wafer 128b enters with its right-hand front region through the inner lock 126 into the bath 114, top side 129 and underside 130 are electrically connected to one another by the bath 114. In a manner similar, in principle, to that in the case of the electrolytic coating described above, a current flows which brings about an electrolytic metal coating from the bath 114 on the irradiated underside 130 since the latter has a negative potential. This electrolytic coating proceeds for as long as the underside 130 is irradiated by the left-hand light source 132 and therefore current also flows. This means that, in a manner similar to that in the case of the above-described electrical contact-connection with the left-hand cathodic roller 19 in accordance with FIG. 1, the left-hand end region of the wafer 128 is no longer irradiated with light when it enters into the bath 114. For this reason, the right-hand light source 132 can additionally be provided, which ensures that the wafer 128b is already completely and a certain piece within the bath 114 for an electrolytic metal deposition constrained by current flow. However, the right-hand light source 132 is not entirely absolutely necessary. It brings about, in a manner similar to that explained for the right-hand cathodic roller 19, longer illumination of the underside 130 of the wafer 128b for the electrolytic build-up of a layer in order that then, in turn, the chemical coating from the bath 114 continues over the whole area and independently. In the position of the right-hand wafer 128c, in turn, a chemical coating then actually continues automatically, in a manner similar to that described for FIG. 1.

While the left-hand light source 132 can be arranged relatively easily outside the bath 114 and should give rise to hardly any problems during operation, this is actually somewhat more complicated for the right-hand light source 132. In order to avoid possible tightness problems or the like here, provision could also be made for configuring the coating tank 113 as light-transmissive in the left-hand region and for arranging the left-hand light source 132 in such a way that it also radiates into the bath 114. It can thus irradiate the underside 130 there, too, in a manner similar to that illustrated by the right-hand light source 132. Devices such as mirrors or optical waveguides or the like would also be possible here.

The cathodic rollers 19 can be embodied in various ways, for example in accordance with US 2008/116059 A1. With regard to the embodiment of the light sources 132, reference is made to known prior art, for example DE 10 2007 038 120 A1.

A coating with nickel takes place on a front grid on a wafer 28, structuring having been effected here by means of either chemical opening or laser structuring of the antireflection layer. Furthermore, a nickel coating can be effected on a phosphorus-doped silicon wafer, in which case here the nickel is deposited only thinly and serves as a conductive layer in order then to be reinforced with an electrolytic coating. This subsequent electrolytic coating can be effected with silver or copper, for example.

Furthermore, it is actually possible for both the current source 21 and the light sources 132 not to be operated in continuous fashion, but rather in pulsed fashion. In this case, too, it is possible to achieve an improvement in the coating, as is known for example from DE 10 2007 038 120 A1 cited above.

1. A method for treating a wafer for solar cell production in a continuous method in a coating bath, wherein, in said coating bath, metal such as nickel, copper or silver is deposited on said wafer, wherein said wafer is introduced into said coating bath and, at a point in time at which said wafer already extends into said coating bath with a first region and does not yet project into said coating bath with a second region, a short current surge is applied to said second region of said wafer in order to initiate an automatic deposition of said metal on said first region of said wafer extending said the coating bath for a subsequent more extensive coating with said wafer having been completely introduced into said coating bath, also on a remaining area of said wafer, without a further current surge or other activation from outside.

2. The method according to claim 1, wherein said short current surge is effected by irradiation of said second region of the wafer with light.

3. The method according to claim 2, wherein said irradiation is effected to an underside of said wafer to be coated with said light from below.

4. The method according to claim 1, wherein said short current surge is effected by application of voltage to said second region of said wafer.

5. The method according to claim 4, wherein said application of voltage to said second region is effected by contact means arranged outside said coating bath.

6. The method according to claim 1, wherein said contact means are provided before said coating bath on that side of said wafer which is to be coated, in order to apply said voltage as a DC voltage.

7. The method according to claim 6, wherein said contact means are applied with negative polarity to said underside of said wafer.

8. The method according to claim 1, wherein said wafer in said coating bath is at least partly wetted on both sides with said coating bath.

9. The method according to claim 8, wherein said wafer is completely immersed and wetted on both sides.

10. The method according to claim 1, wherein said coating on said underside of said wafer is effected in said coating bath.

11. The method according to claim 1, wherein said wafer is irradiated with light or wherein voltage is applied to said wafer at most for as long as said wafer has not yet been completely moved into said coating bath.

12. The method according to claim 1, wherein a duration of said current surge is less than 5 sec.

13. The method according to claim 1, wherein a duration of said current surge is less than 2 sec.

14. The method according to claim 1, wherein by said coating with nickel or copper, elongate conductor fingers are applied to said wafer.

15. The method according to claim 14, wherein said fingers are applied to said underside of said wafers.

16. A device for carrying out the method according to claim 1, being provided with a coating bath with a continuous-passage path and a light source below or above said continuous-passage path for a momentary irradiation of an incoming wafer with light for the purpose of coating in said coating bath.

17. The device for carrying out the method according to claim 1, being provided with a coating bath with a continuous-passage path and contact means below or above said continuous-passage path for a momentary electrical contact-connection of an incoming wafer for the purpose of coating in said coating bath.
